(19) United States
(12) Patent Application Publication
(10) Pub. No.: US 2011/0094723 A1
(43) Pub. Date: Apr. 28, 2011

(54) COMBINATION OF FASTENER AND THERMAL-CONDUCTING MEMBER

(76) Inventors: George Anthony Meyer, IV, San Jose, CA (US); Chien-Hung Sun, Zhongli City (TW); Chieh-Ping Chen, Zhongli City (TW)

(21) Appl. No.: 12/605,804

(22) Filed: Oct. 26, 2009

(51) Int. Cl. H01L 23/40; F28F 7/00

(52) U.S. Cl. 165/185

(57) ABSTRACT

A combination of a fastener and a thermal-conducting member is mounted on an electronic heat-generating member. The fastener includes a plate provided with an opening for allowing the electronic heat-generating element to be disposed therein; posts connected to the plate and formed around the opening; and clamping arms extending from the plate opposite to the posts. The thermal-conducting member is disposed on the plate to span the opening. The clamping arms are bent to press in the thermal-conducting member, thereby forming on the surface of the thermal-conducting member with a plurality of positioning notches for allowing the clamping arms to be inserted therein. With this arrangement, the fastener can be combined with the thermal-conducting member tightly. Thus, the heat generated by the electronic heat-generating element can be continuously conducted to the outside, so that the temperature of the electronic heat-generating element can be kept in a normal range.

### BACKGROUND OF THE INVENTION

1. Field of the Invention

The present invention relates to a combination of a fastener and a thermal-conducting member, and in particular to a combination of a fastener and a thermal-conducting member that is mounted on an electronic heat-generating element.

2. Description of Prior Art

With the advancement of science and technology, the power of an electronic heat-generating element (such as a CPU) increases significantly. As a result, the heat generated by the electronic heat-generating element is increased greatly. Thus, a heat sink with stronger heat-dissipating effect is needed to dissipate the heat generated by the electronic heat-generating element, so that the normal operation of the electronic heat-generating element may not be affected. A conventional way of dissipating the heat generated by the electronic heat-generating element is to secure a heat sink by a fastener to a circuit board on which the electronic heat-generating element is mounted, so that the heat sink can be brought into thermal contact with the electronic heat-generating element. With such a vertically stacked structure, the heat generated by the electronic heat-generating element can be dissipated to the outside rapidly. However, since electronic products are made more and more compact, the vertical space near the electronic heat-generating element is reduced. Accordingly, another solution is proposed, in which a thermal-conducting plate is used to conduct the heat generated by the electronic heat-generating element to a heat sink remote from the electronic heat-generating element, and then the heat sink dissipates the heat to the outside. With such an arrangement, the vertical space necessary for dissipating the heat of the electronic heat-generating element can be reduced, thereby conforming to the requirement for compactness.

However, in the above-mentioned conventional art, the thermal-conducting plate is secured to the fastener by soldering with soldering tin or by binding with heat-dissipating glue. Then, screws pass through fixing holes of the fastener to secure the thermal-conducting plate and the fastener to the circuit board. During the fixing process of the screws, if the fixing force of the screw is larger than a feedback force exerted by a chip, the fastener may be warped due to the uneven fixing forces of the screws. As a result, the thermal-conducting member may be separated from the fastener, so that the thermal-conducting member cannot contact the electronic heat-generating element tightly, which will deteriorate the thermal-conducting effect.

Therefore, it is an important issue for the present Inventor to solve the above-mentioned problems.

### SUMMARY OF THE INVENTION

The present invention is to provide a combination of a fastener and a thermal-conducting member, whereby the fastener can be secured tightly to the thermal-conducting member. Thus, the fastener will not warp to be separate from the thermal-conducting member.

The present invention is to provide a combination of a fastener and a thermal-conducting member, which is mounted on an electronic heat-generating member and includes a fastener and a thermal-conducting member. The fastener includes: a plate provided with an opening for allowing the electronic heat-generating element to be disposed therein; a plurality of posts connected to the plate and formed in an outer periphery of the opening respectively; and a plurality of clamping arms extending from the plate and located on one side opposite to the posts. The thermal-conducting member is disposed on the plate to span the opening. The surface of the thermal-conducting member is formed with a plurality of positioning notches for allowing the clamping arms to be inserted therein.

The present invention is to provide a combination of a fastener and a thermal-conducting member, which is mounted on an electronic heat-generating member and includes a fastener and a thermal-conducting member. The fastener includes a plate provided with an opening for allowing the electronic heat-generating element to be disposed therein; a plurality of posts connected to the plate and formed in an outer periphery of the opening respectively; and a plurality of clamping arms extending from the plate and located on one side opposite to the posts. The thermal-conducting member is disposed on the plate to span the opening. The clamping arms are bent to press in the thermal-conducting member, thereby forming on the surface of the thermal-conducting member with a plurality of positioning notches for allowing the clamping arms to be inserted therein.

In comparison with prior art, the present invention has advantageous features as follows:

(1) Since the clamping arms of the fastener are inserted into the positioning notches of the thermal-conducting member, the thermal-conducting member may not slide with respect to the fastener. Further, the clamping arms and the positioning notches are soldered together. Thus, with dual effects of mechanical clamping and soldering, the fastener and the thermal-conducting member can be assembled together to form a structure that is more rigid to resist the warping of the fastener. Thus, during the process of securing the screws on the circuit board, the problem in prior art that the fastener may warp to be separated from the thermal-conducting member can be overcome.

(2) Since the clamping arms are inserted into the positioning notches with the top surfaces of the clamping arms being in flush with the top surface of the thermal-conducting member, such an arrangement can strengthen the fastening effect of the fastener without increasing the vertical height of the whole combination on the circuit board. Thus, it conforms to the requirement for compactness.

(3) According to the present invention, the clamping arms of the fastener can be bent directly to press in the thermal-conducting member by a larger pressing force, thereby forming the positioning notches on the surface of the thermal-conducting member until the top surfaces of the clamping arms are in flush with the top surface of the thermal-conducting member. In this way, the fastener can be assembled with the thermal-conducting member tightly, and it is unnecessary to form the positioning notches on the thermal-conducting member in advance, which simplifies the manufacturing and assembling process.

### BRIEF DESCRIPTION OF THE DRAWINGS

FIG. 1 is an exploded perspective view of the present invention;

FIG. 2 is an assembled perspective view of the present invention;

FIG. 3 is an assembled perspective view of the present invention taken from another viewing angle;

FIG. 4 is an assembled cross-sectional view of the present invention;

FIG. 5 is a cross-sectional view showing the present invention being applied to an electronic heat-generating element of a circuit board; and

FIG. 6 is a cross-sectional view showing the present invention being applied to an electronic heat-generating element of a circuit board taken from another viewing angle.

### DETAILED DESCRIPTION OF THE INVENTION

The characteristics and technical contents of the present invention will be explained with reference to the accompanying drawings. However, the drawings are illustrative only but not used to limit the present invention.

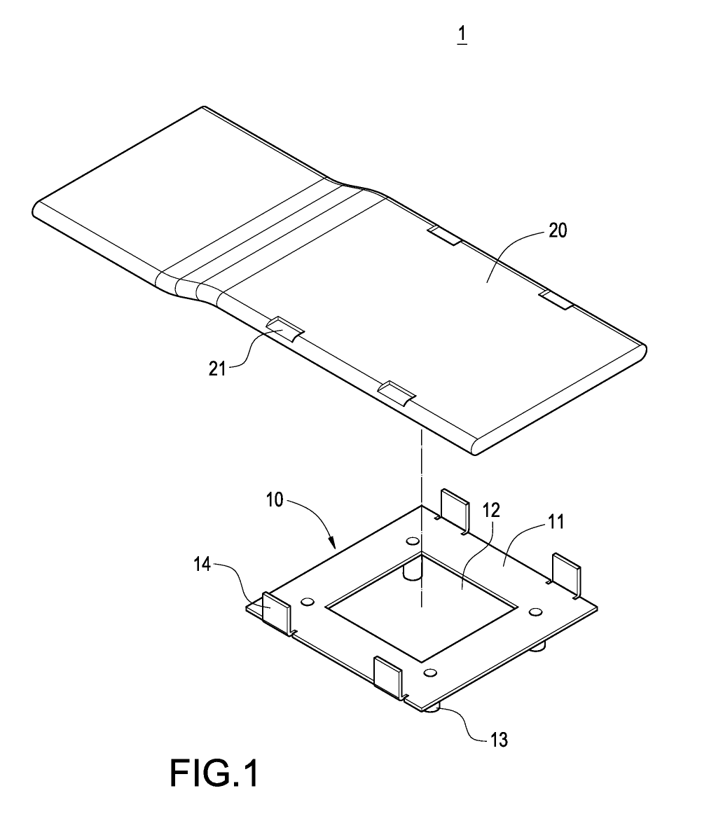

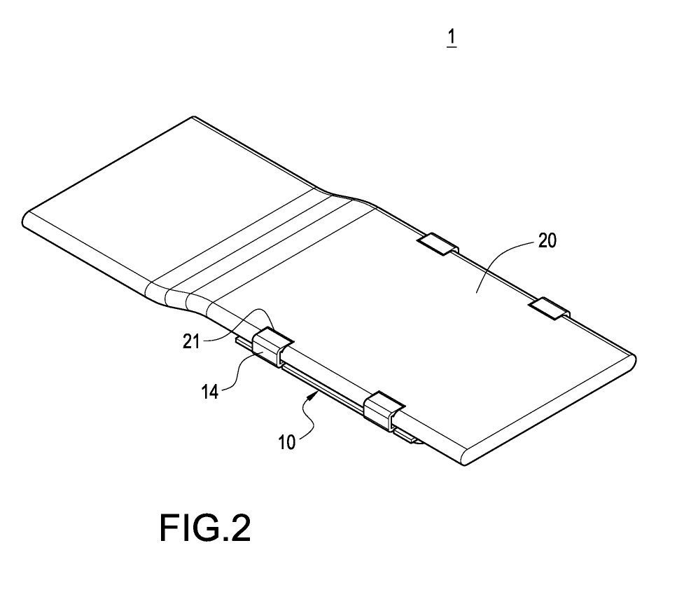

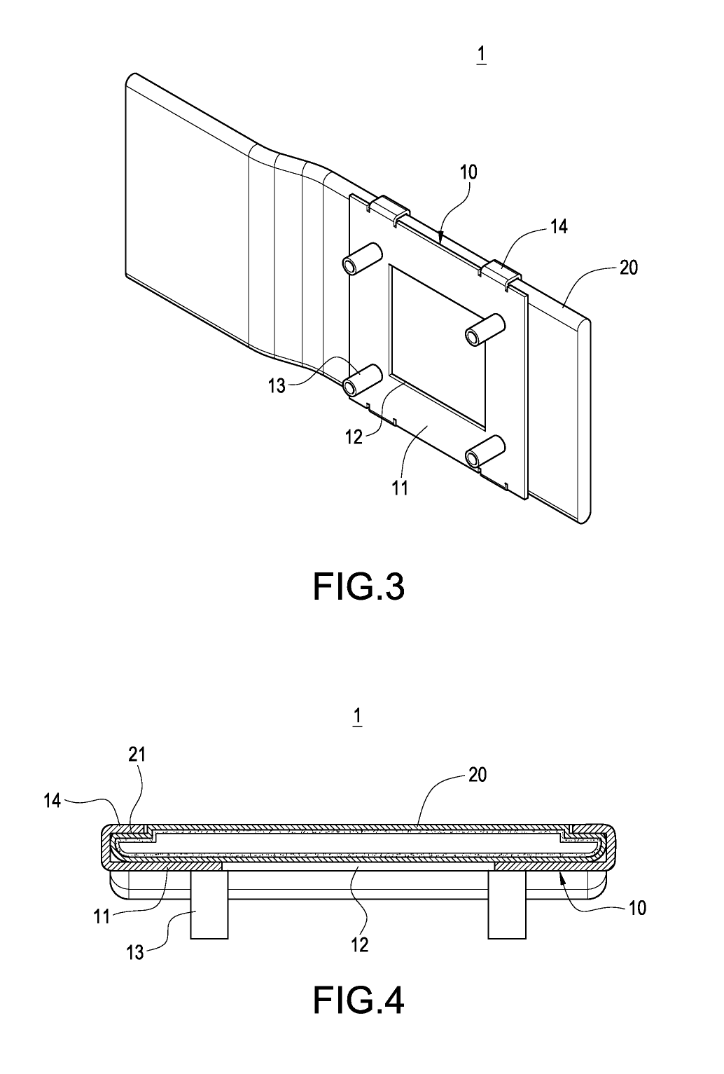

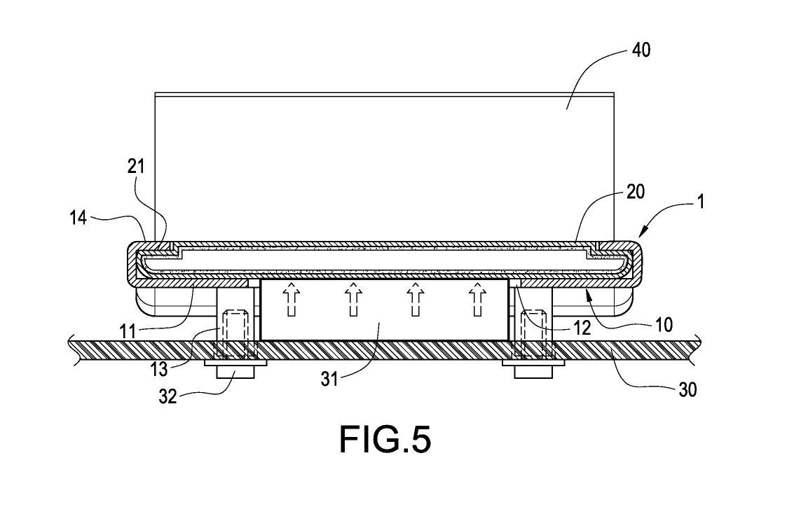

Please refer to FIGS. 1 to 3. FIG. 1 is an exploded perspective view of the present invention. FIG. 2 is an assembled perspective view of the present invention, and FIG. 3 is an assembled perspective view of the present invention taken from another viewing angle. The present invention provides a combination 1 of a fastener and a thermal-conducting member, which includes a fastener 10 and a thermal-conducting member 20. As shown in FIG. 5, the combination 1 is mounted on a circuit board 30 of an electronic heat-generating element 31 by means of screws 32. With this combination 1, the heat of the electronic heat-generating element 31 can be dissipated to the outside quickly, thereby keeping the working temperature of the electronic heat-generating element 31 in a normal range.

The fastener 10 is a thin plate made of metallic materials such as aluminum or copper for fastening the thermal-conducting member 20. The fastener 10 is constituted of a quadrilateral plate 11. The center of the plate 11 is provided with an opening 12 for allowing the electronic heat-generating element 31 to be disposed therein. The outer periphery of the opening 12 extends downwards to form a plurality of posts 13 (four in the drawings). A screw hole (not shown) is provided in each of the posts 13, whereby the screws 32 can pass through the screw holes respectively to secure the fastener 10 to the circuit board 30. Two opposite edges of the plate 11 are bent upwards to form a plurality of L-shaped clamping arms 14 (four in the drawings). These clamping arms 14 are located on one side opposite to the posts 13.

The thermal-conducting member 20 is a vapor chamber that is disposed on the plate 11 to span the opening 12. The thermal-conducting member 20 is used to dissipate the heat generated by the electronic heat-generating element 31 to the outside rapidly. Two opposite edges of the thermal-conducting member 20 can be formed with a plurality of positioning notches 21 (four in the drawings) by a pressing process.

It should be noted that the dimension and location of each of the clamping arms 14 of the fastener 10 correspond to those of the positioning notches 21 of the thermal-conducting member 20. With this arrangement, as shown in FIG. 4, the clamping arms 14 can be inserted into the positioning notches 21 with the top surfaces of the clamping arms 14 being in flush with the top surface of the thermal-conducting member 20. Thus, the fastener 10 can be assembled with the thermal-conducting member 20 tightly so as to the combination 1 of the present invention. In the present invention, the posts 13 and the clamping arms 14 are located near four corners of the plate 11, so that the stress on the plate 11 can be distributed uniformly.

Alternatively, in practice, the fastener 10 can be aligned with the thermal-conducting member 20. Then, a die (not shown) is used to bend the clamping arms 14 to press in the thermal-conducting member 20 directly. Thereafter, a larger pressing force is exerted to press in the thermal-conducting member 20, so that the surface of the thermal-conducting member 20 is sunk to form the positioning notches 21 until the top surfaces of the clamping arms 14 are in flush with the top surface of the thermal-conducting member 20. In this way, a larger fastening effect can be obtained. Of course, in this manner, it is unnecessary to form the positioning notches 21 on the thermal-conducting member 20 in advance. Further, it is unnecessary to align the clamping arms 14 with the positioning notches 21 before performing the bending and pressing process. Thus, the time for manufacturing and assembling the present invention can be reduced.

It should be noted that, since the positioning notches 21 are located on both side edges of the thermal-conducting member 20, the thermal-conducting member 20 cannot slide with respect to the fastener 10 when the clamping arms 14 are inserted into the positioning notches 24 with the top surfaces of the clamping arms 14 being in flush with the top surface of the thermal-conducting member 20.

Next, the clamping arms 14 and the positioning notches 21 can be soldered together. In this way, the mechanical fastening effect between the clamping arms 14 and the positioning notches 21, and the binding effect caused by the soldering process can fix the clamping arms 14 in the positioning notches 21 firmly. Thus, the fastener 10 can be fixed to the thermal-conducting member 20 tightly and firmly.

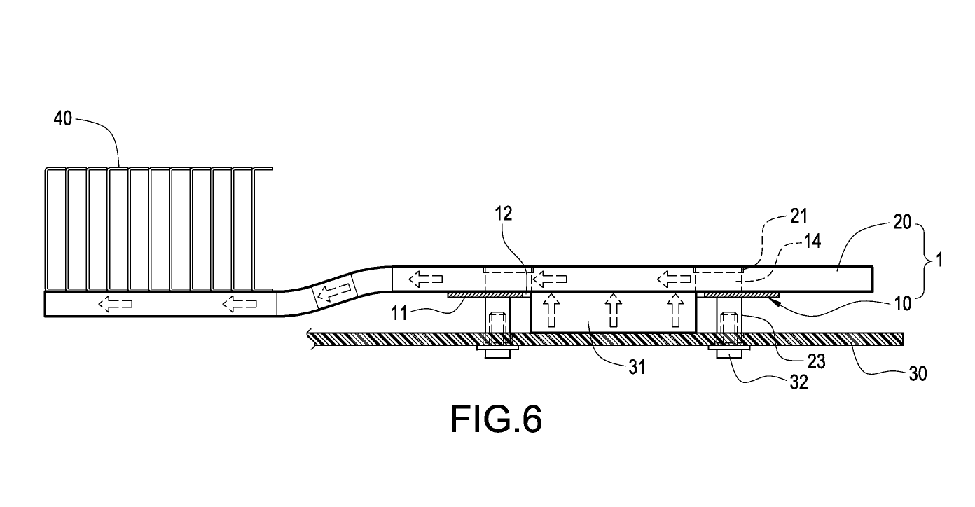

Please refer to FIGS. 5 and 6, which show the combination 1 of a fastener and a thermal-conducting member according to the present invention being mounted on the circuit board 30. After the fastener 10 and the thermal-conducting member 20 are assembled with each other in the above-mentioned manner to form the combination 1, an operator aligns the opening 12 of the fastener 10 with the electronic heat-generating element 31. Then, the operator uses the screws 32 to pass through the bottom surface of the circuit board 30, thereby screwing into the posts 13 of the fastener 10. Thus, the whole combination 1 can be fixed to the circuit board 30 by the screws 32. As shown in FIG. 5, since the length of each post 13 is designed in such a manner that the top surface of the electronic heat-generating element 31 can protrude slightly from the opening 12 to be thermally contact the bottom surface of the thermal-conducting member 20, the heat generated by the electronic heat-generating element 31 can be conducted to the thermal-conducting member 20 (indicated by the arrows in FIG. 5). Then, the thermal-conducting member 20 continuously conducts the heat to a heat sink 40 that is arranged at the other end of the thermal-conducting member 20 and remote from the electronic heat-generating element 31 (indicated by the arrows in FIG. 6). In this way, the heat can be dissipated to the outside, and the temperature of the electronic heat-generating element 31 can be kept in a normal range.

Since the fastener 10 and the thermal-conducting member 20 are combined together with the dual effects caused by mechanical fixing and soldering, the combination 1 can form a structure that is more rigid to resist any possible warping. Therefore, during the process of securing the screws 32 on the circuit board 30, the combination 1 will not warp, and the fastener 10 will not be separated from the thermal-conducting member 20.

In the present invention, since the clamping arms 14 of the fastener 10 are inserted into the positioning notches 21 of the thermal-conducting member 20 with the top surfaces of the clamping arms 14 being in flush with the top surface of the thermal-conducting member 20, the vertical height of the whole combination 1 on the circuit board 30 is identical to the sum of thickness of the electronic heat-generating element 31 and the thermal-conducting member 20. Thus, in the condition that an electronic produce is made compact to inevitably reduce the space above the circuit board, the combination 1 of the present invention really achieves a good thermal-conducting and heat-dissipating effect, and it can be fixed to the circuit board 30 tightly without warping or separating there from.

According to the above, the combination of a fastener and a thermal-conducting member according to the present invention really demonstrates industrial applicability, novelty and inventive steps. Further, the structure of the present invention has not been seen in product of the same kind or let in public use. Thus, the present invention conforms to the requirements for a utility model patent.

What is claimed is:

1. A combination of a fastener and a thermal-conducting member, mounted on an electronic heat-generating member, including:
a fastener, including:
a plate provided with an opening for allowing the electronic heat-generating element to be disposed therein;
a plurality of posts connected to the plate and formed in an outer periphery of the opening respectively; and
a plurality of clamping arms extending from the plate and located on one side opposite to the posts; and
a thermal-conducting member disposed on the plate to span the opening, the surface of the thermal-conducting member being formed with a plurality of positioning notches for allowing the clamping arms to be inserted therein.

2. The combination of a fastener and a thermal-conducting member according to claim 1, wherein the thermal-conducting member is a vapor chamber.

3. The combination of a fastener and a thermal-conducting member according to claim 1, wherein the plate is quadrilateral, and the clamping arms are bent from two opposite sides of the plate.

4. The combination of a fastener and a thermal-conducting member according to claim 3, wherein each of the clamping arms is formed into an L shape.

5. The combination of a fastener and a thermal-conducting member according to claim 3, wherein the positioning notches are formed on two opposite edges of the thermal-conducting member by pressing.

6. The combination of a fastener and a thermal-conducting member according to claim 3, wherein top surfaces of the clamping arms are in flush with a top surface of the thermal-conducting member.

7. A combination of a fastener and a thermal-conducting member, mounted on an electronic heat-generating member, including:
a fastener, including:
a plate provided with an opening for allowing the electronic heat-generating element to be disposed therein;
a plurality of posts connected to the plate and formed in an outer periphery of the opening respectively; and
a plurality of clamping arms extending from the plate and located on one side opposite to the posts; and
a thermal-conducting member disposed on the plate to span the opening, the clamping arms being bent to press in the thermal-conducting member, thereby forming on the surface of the thermal-conducting member with a plurality of positioning notches for allowing the clamping arms to be inserted therein.

8. The combination of a fastener and a thermal-conducting member according to claim 7, wherein the thermal-conducting member is a vapor chamber.

9. The combination of a fastener and a thermal-conducting member according to claim 7, wherein the plate is quadrilateral, and the clamping arms are bent from two opposite sides of the plate.

10. The combination of a fastener and a thermal-conducting member according to claim 9, wherein each of the clamping arms is formed into an L shape.

11. The combination of a fastener and a thermal-conducting member according to claim 9, wherein the positioning notches are formed on two opposite edges of the thermal-conducting member.

12. The combination of a fastener and a thermal-conducting member according to claim 9, wherein top surfaces of the clamping arms are in flush with a top surface of the thermal-conducting member.
